(19) United States
(12) Patent Application Publication
(10) Pub. No.: US 2011/0177638 A1
(43) Pub. Date: Jul. 21, 2011

(54) SEMICONDUCTOR LIGHT EMITTING DEVICE WITH CURVATURE CONTROL LAYER

(75) Inventors: Linda T. ROMANO, Sunnyvale, CA (US); Byung-kwon HAN, Santa Clara, CA (US); Michael D. CRAVEN, San Jose, CA (US)

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/687,940

(22) Filed: Jan. 15, 2010

(51) Int. Cl. H01L 33/00

(52) U.S. Cl. 438/29; 438/47; 257/E33.025; 257/E33.068

(57) ABSTRACT

A semiconductor structure is grown on a top surface of a growth substrate. The semiconductor structure comprises a III-nitride light emitting layer disposed between an n-type region and a p-type region. A curvature control layer is disposed in direct contact with the growth substrate. The growth substrate has a thermal expansion coefficient less than a thermal expansion coefficient of GaN and the curvature control layer has a thermal expansion coefficient greater than the thermal expansion coefficient of GaN.

### BACKGROUND

1. Field of Invention

The present invention relates to a semiconductor light emitting device grown on a substrate including a curvature control layer.

2. Description of Related Art

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions.

U.S. Pat. No. 7,612,361 teaches “[c]hiefly, the nitride single crystal is grown on a hetero-substrate such as a sapphire substrate . . . or a SiC substrate via a Vapor Phase Growth method such as Metal Organic Chemical Vapor Deposition (MOCVD) or Hydride Vapor Phase Epitaxy (HVPE), or a Molecular Beam Epitaxy method (MBE). However, due to expensiveness and size limited to 2 or 3 inches, disadvantageously, the single crystal sapphire substrate or SiC substrate is inappropriate for mass-production. Therefore, in the art, a Si substrate which is in common use in the semiconductor industry needs to be adopted. But, owing to differences in lattice constant and thermal expansion coefficient between the Si substrate and a GaN single crystal, a GaN layer suffers too many defects and cracks to be commercialized.”

“According to a conventional method to overcome this problem, a buffer layer may be formed on the Si substrate.” One example of a buffer layer is “an AlN buffer layer . . . formed on (111) crystal plane of a Si substrate . . . , an AlₓGa₁₋ₓN intermediate layer . . . grown to a total thickness of 300 nm, with its Al composition ratio (x) varied in a range of about 0.87 to 0.07, and a GaN single crystal . . . grown on the AlₓGa₁₋ₓN intermediate layer . . . to a thickness of 2 μm.”

### SUMMARY

It is an object of the invention to provide a III-nitride light emitting device grown on a substrate on which a curvature control layer is formed.

In embodiments of the invention, a semiconductor structure is grown on a top surface of a growth substrate. The semiconductor structure comprises a III-nitride light emitting layer disposed between an n-type region and a p-type region. A curvature control layer is disposed in direct contact with the growth substrate. The growth substrate has a thermal expansion coefficient less than a thermal expansion coefficient of GaN and the curvature control layer has a thermal expansion coefficient greater than the thermal expansion coefficient of GaN.

### BRIEF DESCRIPTION OF THE DRAWINGS

FIG. 1 illustrates a light emitting device grown on a substrate with a curvature control layer on the bottom surface of the substrate.

FIG. 2 illustrates the structure of FIG. 1 formed into a thin-film flip-chip device.

FIG. 3 illustrates wafer curvature as a function of growth time for III-nitride structures grown on sapphire, grown on Si without a curvature control layer, and grown on Si with a curvature control layer.

FIG. 4 illustrates a light emitting device grown on a substrate with a curvature control layer on the top surface of the substrate.

FIG. 5 illustrates a light emitting device grown on a substrate with curvature control layers on both the top and bottom surfaces of the substrate.

### DETAILED DESCRIPTION

The modulus, thermal expansion coefficient, thermal expansion percentage relative to GaN, and thermal conductivity at 300 K for GaN, Si, and sapphire are illustrated in the table below:

| | | | | Thermal |
|---|---|---|---|---|
| | Modulus | Thermal Expansion | Thermal | Conductivity |
| | (MPa) | (10⁻⁶/K) | Expansion (%) | (W/mK) |
| GaN | 260 | 5.59 | | 130 |
| Si | 120 | 2.59 | −50% | 149 |
| | | | (tensile) | |
| Al₂O₃ | 500 | 7.50 | +35% | 30 |
| | | | (compressive) | |

According to the thermal expansion coefficients, GaN growth on Si results in tensile curvature on cool-down, meaning that the GaN film is being pulled apart, while GaN growth on sapphire results in compressive curvature, meaning that the GaN film is being compressed together. Si has the lowest modulus (and melting temperature), indicating that its relative strength is weak compared to both GaN and sapphire, especially at growth temperatures of GaN, which may exceed 1000° C. Accordingly, films of either GaN or Al₂O₃ formed on a Si substrate can influence the nature of bowing and cracking in the system, depending on the relative thicknesses of the film and the substrate.

In embodiments of the invention, a curvature control layer is formed on a substrate, to reduce curvature induced by the thermal mismatch between the semiconductor material and the substrate. In some embodiments, the semiconductor material is III-nitride material and the growth substrate is Si, though other semiconductor materials and other substrates may be used. A curvature control layer may be formed on the front side of the substrate, (i.e. the surface on which the III-nitride material is grown), the back side of the substrate, or both sides of the substrate.

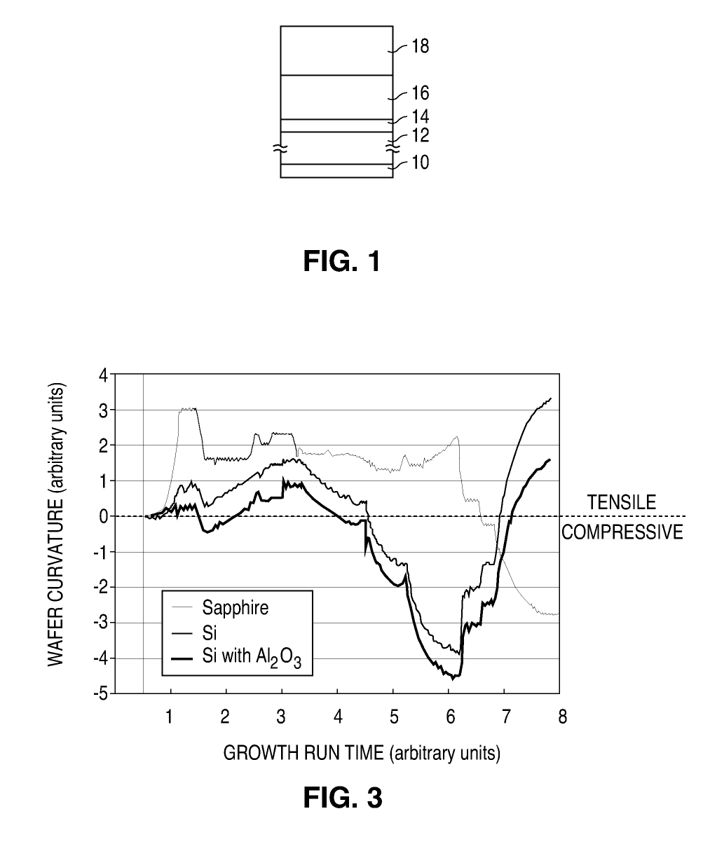

FIG. 1 illustrates an embodiment of the invention. Curvature control layer 10 is formed on the back side of growth substrate 12. In some embodiments, curvature control layer 10 is a material that can withstand the processing conditions required to form the device, with a larger thermal expansion coefficient than growth substrate 12. In some embodiments, curvature control layer 10 is a material that also has a larger modulus than the growth substrate 12.

The thickness of curvature control layer 10 may be determined by the thickness of growth substrate 12, the thickness of the semiconductor material grown on the growth substrate 12, the modulus of the curvature control layer material, and the magnitude of the difference between the thermal expansion coefficients of growth substrate 12 and curvature control layer 10. For example, in general, to achieve a given level of influence on the curvature caused by thermal mismatch, a thinner curvature control layer may be used when the thickness of the growth substrate is small, a thinner curvature control layer may be used when the thickness of the grown semiconductor material is small, a thicker curvature control layer may be used when the modulus of the curvature control layer is small, and a thicker curvature control layer may be used as the difference between the thermal expansion coefficients of growth substrate 12 and curvature control layer 10 decreases.

In some embodiments, growth substrate 12 is silicon, a material with a smaller coefficient of thermal expansion than that of GaN, and curvature control layer 10 is Al₂O₃, a material with a larger coefficient of thermal expansion than that of GaN. Curvature control layer 10 may be, for example, polycrystalline α-Al₂O₃ which is sputter deposited or e-beam evaporated on substrate 12. A polycrystalline Al₂O₃ curvature control layer 10 formed on the back side of a Si substrate may be between 50 nm and 5 microns thick in some embodiments, between 50 nm and 1 micron thick in some embodiments, between 50 nm and 500 nm thick in some embodiments, between 100 and 300 nm thick in some embodiments, and 200 nm thick in some embodiments. The Si substrate may be between 200 microns and 5 mm thick in some embodiments, between 300 microns and 2 mm thick in some embodiments, and between 400 microns and 1 mm thick in some embodiments. In some embodiments, a larger diameter substrate is thicker than a smaller diameter substrate. Examples of suitable diameters include 3 inches, 6 inches, and other commercially available Si substrates.

The substrate 12 and curvature control layer 10 are placed in a growth reactor and III-nitride growth begins. One or more preparation layers are grown on the top surface of the substrate 12, the surface opposite curvature control layer 10 in the device of FIG. 1. Two preparation layers 14 and 16 are shown in the structure illustrated in FIG. 1.

An AlN nucleation layer 14 is grown in direct contact with substrate 12. AlN is often used as a nucleation layer on a Si substrate instead of GaN because gallium undesirably reacts with the surface of the Si substrate. Other nucleation layers that do not decompose or react with Si at the nucleation layer growth temperature, and on which III-nitride materials will nucleate, may be used with a Si substrate, such as ScN. Other nucleation layers may be used with other substrate materials. Nucleation layer may be between 50 nm and 500 nm thick in some embodiments and about 100 nm thick in some embodiments.

A graded buffer region 16 is grown over nucleation layer 14. Graded region 16 may be graded from AlN in a region in contact with nucleation layer 14 to AlGaN in a region in contact with device layers 18. Graded region 16 may be graded from AlN to AlGaN with 90% AlN in some embodiments, to AlGaN with 10% AlN in some embodiments, and to GaN in some embodiments. Graded region 16 may be between 100 and 2000 nm thick in some embodiments. In some embodiments, graded region 16 is omitted and the device layers are grown directly on nucleation layer 14. Including a graded region may allow higher quality and/or thicker device layers to be grown.

In some embodiments, a curvature control layer is formed between the substrate 12 and the semiconductor material, as illustrated in FIG. 4, or curvature control layers 10 are formed on both the front and back sides of the substrate 12, as illustrated in FIG. 5. A curvature control layer disposed between substrate 12 and the preparation layer or layers may be formed such that III-nitride material will nucleate on the curvature control layer.

Device layers 18, which include an n-type region, a light emitting or active region, and a p-type region, are grown over preparation layers 14 and 16. The n-type region is typically grown first and may include multiple layers of different compositions and dopant concentration including, for example, additional preparation layers such as buffer layers or nucleation layers, which may be n-type or not intentionally doped, release layers designed to facilitate later release of the substrate or thinning of the semiconductor structure after substrate removal, and n- or even p-type device layers designed for particular optical or electrical properties desirable for the light emitting region to efficiently emit light. A light emitting or active region is grown over the n-type region. Examples of suitable light emitting regions include a single thick or thin light emitting layer, or a multiple quantum well light emitting region including multiple thin or thick quantum well light emitting layers separated by barrier layers. A p-type region is grown over the light emitting region. Like the n-type region, the p-type region may include multiple layers of different composition, thickness, and dopant concentration, including layers that are not intentionally doped, or n-type layers.

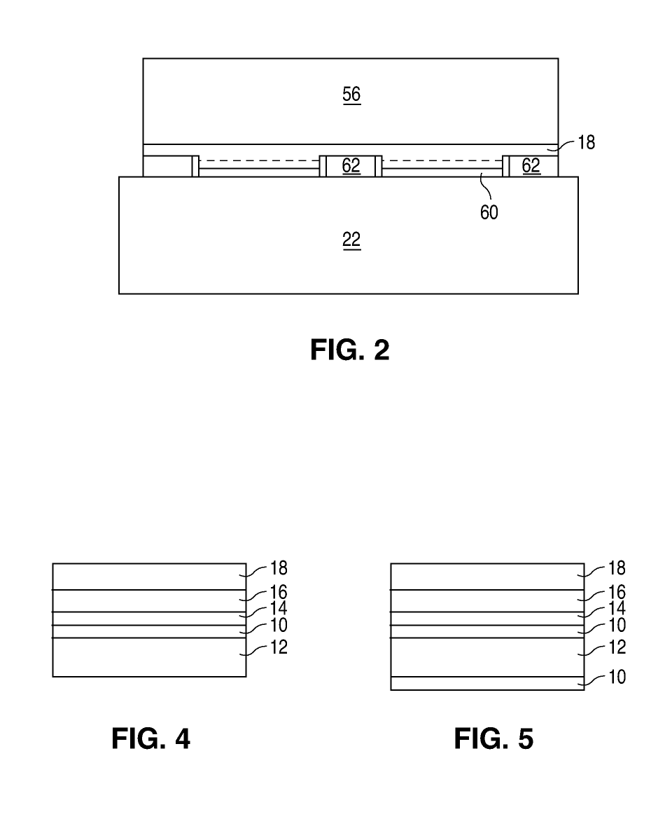

FIG. 2 illustrates the structure of FIG. 1 processed into a thin film flip chip device, where the contacts are formed on the top side of the structure, the structure is flipped over and attached to a mount, then the growth substrate is removed. The structures illustrated in FIGS. 1, 4, and 5 may be processed into any suitable device. Other examples of device structures that may be used include vertical devices, where the n- and p-contacts are formed on opposite sides of the device, flip chip devices where the growth substrate remains a part of the device, and devices where light is extracted through transparent contacts. In some embodiments, substrate 12 is Si, all or a portion of substrate 12 is conductive, curvature control layer 10 is removed from substrate 12 after growth of device layers 18, and an n-contact is formed on the back side of substrate 12.

To form the device illustrated in FIG. 2, a p-contact 60 is formed on the top surface of p-type region. P-contact 60 may include a reflective layer, such as silver. P-contact 60 may include other optional layers, such as an ohmic contact layer and a guard sheet including, for example, titanium and/or tungsten. A portion of p-contact 60, the p-type region, and the active region is removed to expose a portion of the n-type region on which an n-contact 62 is formed.

Interconnects (not shown in FIG. 2) are formed on the p- and n-contacts, then the device is connected to mount 22 through the interconnects. The interconnects may be any suitable material, such as solder or other metals, and may include multiple layers of materials. In some embodiments, interconnects include at least one gold layer and the bond between the LED segments and the mount is formed by ultrasonic bonding. For ultrasonic bonding, the LED die is positioned on a mount. A bond head is positioned on the top surface of the LED die, for example on the top surface of the growth substrate. The bond head is connected to an ultrasonic transducer. The ultrasonic transducer may be, for example, a stack of lead zirconate titanate (PZT) layers. When a voltage is applied to the transducer at a frequency that causes the system to resonate harmonically (often a frequency on the order of tens or hundreds of kHz), the transducer begins to vibrate, which in turn causes the bond head and the LED die to vibrate, often at an amplitude on the order of microns. The vibration causes atoms in the metal lattice of a structure on the LED, such as the n- and p-contacts or interconnects formed on the n- and p-contacts, to interdiffuse with a structure on the mount, resulting in a metallurgically continuous joint. Heat and/or pressure may be added during bonding.

After the semiconductor structure is bonded to mount 22, all or part of the growth substrate may be removed. For example, a polycrystalline Al₂O₃ curvature control layer may be removed by laser lift-off or a mechanical technique such as grinding, polishing, or chemical-mechanical polishing, then the Si substrate may be removed by etching or mechanical techniques such as grinding. After the growth substrate is removed, the semiconductor structure may be thinned, for example by photoelectrochemical (PEC) etching. The exposed surface of the n-type region may be textured, for example by roughening or by forming a photonic crystal. In a vertical device, an n-contact may be formed on the surface of the n-type region exposed by removing the growth substrate. In some embodiments, the growth substrate and curvature control layer remain part of the finished device.

One or more wavelength converting materials 56 may be disposed over the semiconductor structure. The wavelength converting material(s) may be, for example, one or more powder phosphors disposed in a transparent material such as silicone or epoxy and deposited on the LED by screen printing or stenciling, one or more powder phosphors formed by electrophoretic deposition, spray coating, or sedimentation, or one or more ceramic phosphors glued or bonded to the LED, one or more dyes, or any combination of the above-described wavelength converting layers. Ceramic phosphors, also referred to as luminescent ceramics, are described in more detail in U.S. Pat. No. 7,361,938, which is incorporated herein by reference. The wavelength converting materials may be formed such that a portion of light emitted by the light emitting region is unconverted by the wavelength converting material. In some examples, the unconverted light is blue and the converted light is yellow, green, and/or red, such that the combination of unconverted and converted light emitted from the device appears white.

In some embodiments, one or more lenses, polarizers, dichroic filters or other optics known in the art are formed over the wavelength converting layer 56 or between wavelength converting layer 56 and device layers 18.

In structures as illustrated in FIG. 1 with a Si substrate 12, a 200 nm thick polycrystalline Al₂O₃ curvature control layer 10, a 0.5 micron thick preparation layer structure of AlN nucleation layer 14 and AlGaN graded region 16, and with a 1.5 micron thick GaN layer substituting for device layers 18, the inventors observed a reduction in tensile curvature on cool down from the GaN growth temperature, as compared to structures grown on a Si substrate without curvature control layer 10. Some curvature reduction was also observed in the initial heating of the wafer due to the thermal conductivity of the polycrystalline Al₂O₃ curvature control layer 10.

FIG. 3 illustrates the curvature of three wafers as a function of growth time. A 0.5 micron thick preparation layer structure of AlN nucleation layer 14 and AlGaN graded region 16, and a 1.5 micron thick GaN layer were grown on three substrates, a sapphire substrate and two Si substrates of the same thickness, one with a polycrystalline Al₂O₃ curvature control layer as illustrated in FIG. 1 and one without. The initial heat up occurs from 0 to 1.5 in the arbitrary units shown for growth run time on FIG. 3, III-nitride growth occurs from 1.5 to 6, and cool down occurs from 6 to 8 seconds. Growth on the Si substrate without the curvature control layer showed a tensile curvature of 1 arbitrary unit as illustrated in FIG. 3 on initial heat up due to a thermal gradient across the wafer. After cool down, the final tensile curvature is 3 arbitrary units. For the Si substrate with a curvature control layer, no curvature was observed during heat up. After cool down after growth of the GaN layer, the final tensile curvature is 1.5 arbitrary units. Fewer cracks were observed on the Si substrate with the curvature control layer, as compared with to the Si substrate without the curvature control layer. For comparison, growth on a sapphire substrate results in a tensile curvature of 3 arbitrary units on initial heat up due to the thermal gradient across the sapphire, and a final curvature after cool down of 3 arbitrary units in compression.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A method comprising:
growing a semiconductor structure on a top surface of a growth substrate, wherein:
the semiconductor structure comprises a III-nitride light emitting layer disposed between an n-type region and a p-type region;
the growth substrate has a thermal expansion coefficient less than a thermal expansion coefficient of GaN;
a curvature control layer is disposed in direct contact with the growth substrate; and
the curvature control layer has a thermal expansion coefficient greater than the thermal expansion coefficient of GaN.

2. The method of claim 1 wherein the growth substrate is silicon.

3. The method of claim 1 wherein the curvature control layer comprises polycrystalline α-Al₂O₃.

4. The method of claim 1 wherein the curvature control layer is disposed on a bottom surface of the growth substrate.

5. The method of claim 1 wherein the curvature control layer is disposed between the semiconductor structure and the growth substrate.

6. The method of claim 1 wherein:
the curvature control layer is a first curvature control layer disposed on a bottom surface of the growth substrate; and
a second curvature control layer is disposed between the semiconductor structure and the growth substrate.

7. The method of claim 1 wherein the curvature control layer has a modulus greater than a modulus of the growth substrate.

8. The method of claim 1 further comprising forming n- and p-contacts on the n- and p-type regions.

9. The method of claim 8 wherein the n- and p-contacts are formed on a same side of the semiconductor structure.

10. The method of claim 8 wherein the n- and p-contacts are formed on opposite sides of the semiconductor structure.

11. The method of claim 1 wherein:
the curvature control layer has a thickness between 50 nm and 5 microns; and
the growth substrate has a thickness between 200 microns and 1 mm.

12. The method of claim 1 further comprising removing the growth substrate after growing the semiconductor structure.

13. The method of claim 1 further comprising disposing a lens over the semiconductor structure.
